(19) United States
(12) Patent Application Publication
(10) Pub. No.: US 2014/0233205 A1
(43) Pub. Date: Aug. 21, 2014

(54) MOUNTING APPARATUS

(71) Applicant: François-Xavier Gardes, London (GB)

(72) Inventor: François-Xavier Gardes, London (GB)

(73) Assignee: PiixL Technologies Limited, London (GB)

(21) Appl. No.: 14/241,461

(22) PCT Filed: Aug. 30, 2012
(86) PCT No.: PCT/GB2012/052124

§ 371 Date: Feb. 27, 2014

(30) Foreign Application Priority Data
Aug. 31, 2011 (GB) 1114945.7

(51) Int. Cl. H05K 7/18; F16M 13/02; F16M 11/00

(52) U.S. Cl. CPC H05K 7/18; F16M 11/00; F16M 13/022
USPC 361/825; 248/274.1; 248/231.91; 248/125.8; 248/201

(57) ABSTRACT

A mounting apparatus including a bracket (11) for mounting behind a flat panel display (F). The bracket is able to receive a separate device (e.g. a PC enclosure of other electronic components), such that said device can be slidable and accessible from behind the flat panel display when it is mounted thereto.

The present invention relates to a mounting apparatus, particularly for wall mounting a flat panel display, wherein an enclosure or device can be located behind the display.

### BACKGROUND TO THE INVENTION

Modern flat panel displays are common for entertainment or computer applications and, as a consequence, an internationally recognised standard has been implemented to provide guidelines for mounting these devices. The VESA-FDMI (Video Electronics Standards Association—Flat Display Mounting Interface) Standard lists a range of square/rectangular screw patterns that may be applied to wall or other mounting devices.

Flat panel displays as used with built-in television receivers or for computer monitoring can be mounted to a wall surface with suitable hanging arrangements that utilise the VESA pattern. Other common devices allow for a flat panel display to be mounted for swivel movement by use of an arm extending from a wall mounting plate.

However, a need has also been identified for peripheral devices to be mounted with (i.e. behind) a flat panel display. For example, US2009/0294599 describes a device for mounting a computer unit behind a flat panel display. It includes various provisions for storing cables and adaptors, etc. behind the screen, but the computer unit itself is static. Indeed, the computer unit mounted in the device cannot be removed without clear access to the rear of the display/monitor; which would not be possible if the display were wall mounted.

EP2391194 also describes a rack module for mounting a computer unit behind a flat panel display, where it may pivot to become accessible to a user at a location beyond the side of the screen; however, the rack module is not part of the wall mounting structure and is not designed to support the flat panel display itself. Furthermore, tilting or pivoting the mechanism for access may not always be convenient because this additional step is required before the computer unit can be accessed for use.

The present inventor developed an invention which is described by WO2009056814, wherein a device is proposed for mounting behind a flat panel display with a retractable and/or extendable bay/tray that is extendable to be accessible by a user when the flat panel display is mounted. The device itself may be a personal computer enclosure or gaming console. Such an invention, with a sliding feature where the location of input ports etc. can be semi-permanently fixed at the edge of the screen, is an advantage over the pivoting mechanism of EP2391194. However, subsequent to this invention it was realised that the device required a complete separate component housing to be fabricated which incorporates the retractable tray in addition to a standard mounting device.

The present invention seeks to provide an improvement or alternative to the general concept described by WO2009056814.

### SUMMARY OF THE INVENTION

In one broad aspect the present invention provides a mounting apparatus including a bracket for mounting behind a flat panel display and adapted to receive a separate device, such that said device can be slidable into and out from behind the flat panel display when it is mounted thereto, to be locatable at a range of slidable positions.

In a preferred embodiment the bracket is fixable to or hung from a wall surface and, in turn, the flat panel display is mounted thereto, such that the display is retained at a specified distance from the wall which provides enough room to access a peripheral device that can slide into and out of the bracket. To achieve this preferably the bracket has at least one opening for receiving the device to be located behind the flat panel display.

Preferably the apparatus is a mounting bracket that attaches a flat panel to a wall or stand or the like using standard VESA hole configurations. In addition, as explained, the apparatus allows a separate enclosure or peripheral device to slide into and out from behind the flat panel display without having to remove the mounts and/or remove the flat panel from its position. The enclosure/device is likely to be electronically connected to the flat panel display in some way and will typically be a slim-form PC, media player or similar peripheral device enhancing the functionality of the display.

A further aspect of the invention provides a peripheral device suitable for mating with the bracket, as well as a combination of the mounting bracket and peripheral device which could be supplied together as a set.

The ability of the mounting apparatus of the invention to allow an enclosure to slide within it particularly allows access for the purposes of checks, repair, upgrades and connections as well as allowing the enclosure/device to be positioned close to the edge of a variety of differently sized flat panel displays. According to one embodiment, the device/enclosure can be secured in place to allow permanent access to certain buttons, interfaces, connection ports, etc. preferably at an accessible edge of the flat panel screen. However, the device is generally locatable at any of a range of positions relative to the flat panel display.

A key difference between the invention and the known prior art mentioned above is that, presently, various ways are proposed of using the space that lies behind the display (including in the area between VESA mounting holes) while optimizing total thickness and retaining the ability to slide and adjust to a TV's width. EP2391194 in particular only makes use of the space between the edge of the display and the mounting holes.

The mounting apparatus of the invention also ensures that the enclosure/device can effectively be hidden behind the flat panel, making it more discrete and secure whilst also reducing the need for cabling and specific building work to accommodate the enclosure device separately to the flat panel display.

It is expected that the mounting apparatus will generally be configured to allow sliding of a device/enclosure horizontally, i.e. so it is accessible at the vertical side edges of a mounted rectangular display. However, in alternative forms the bracket may allow for devices to extend in other directions, e.g. for accessibility at a top or bottom peripheral edge of a display. Indeed, a mounting apparatus according to the invention could be configured to receive and enable sliding of a device or multiple devices from several directions at once. It is also conceivable that the computer unit within the mounting apparatus may be extendable (similar to as described in WO2009056814), either in one or both directions laterally out to the edge of the monitor/TV screen. In practice the chassis of the computer can be expandable with a bay extendable from a body portion in order to increase its lateral width. By use of such an expandable system, in a most preferred embodiment, there is the advantage of leaving both sides of a PC at a short distance from each of the TV's edges. This provides an easy access to i/o ports and various controls on one side, and easy access to all the “backpanel” connectors (network, more usb, power) and directs the hot air exhaust away from the TV's rear vents.

As stated, the invention allows enclosure volume to be used behind the TV, and notably within the area inside the four VESA mounting holes. Even in basic embodiments where such volume is provided in the form of a tube (FIGS. 3, 4 and 5), there could be a power button at the end of this tube for example. The invention was conceived to address how to optimize the PC enclosure volume behind the screen, under the constraint of ensuring the lowest possible total thickness.

### BRIEF DESCRIPTION OF THE DRAWINGS

FIG. 1 illustrates a general perspective view of a preferred embodiment of mounting apparatus according to the invention;

FIG. 2 illustrates a general perspective view of a second embodiment of mounting apparatus;

FIG. 3 illustrates a general view of a further embodiment;

FIG. 4 illustrates a general view of a still further embodiment;

FIG. 5 illustrates a general view of a further embodiment of the invention;

FIG. 6 illustrates a general view of a further embodiment of the invention;

FIG. 7 illustrates a general view of a still further embodiment; and

FIG. 8 illustrates a view of internal components of an enclosure for use with the invention.

### DETAILED DESCRIPTION OF THE INVENTION

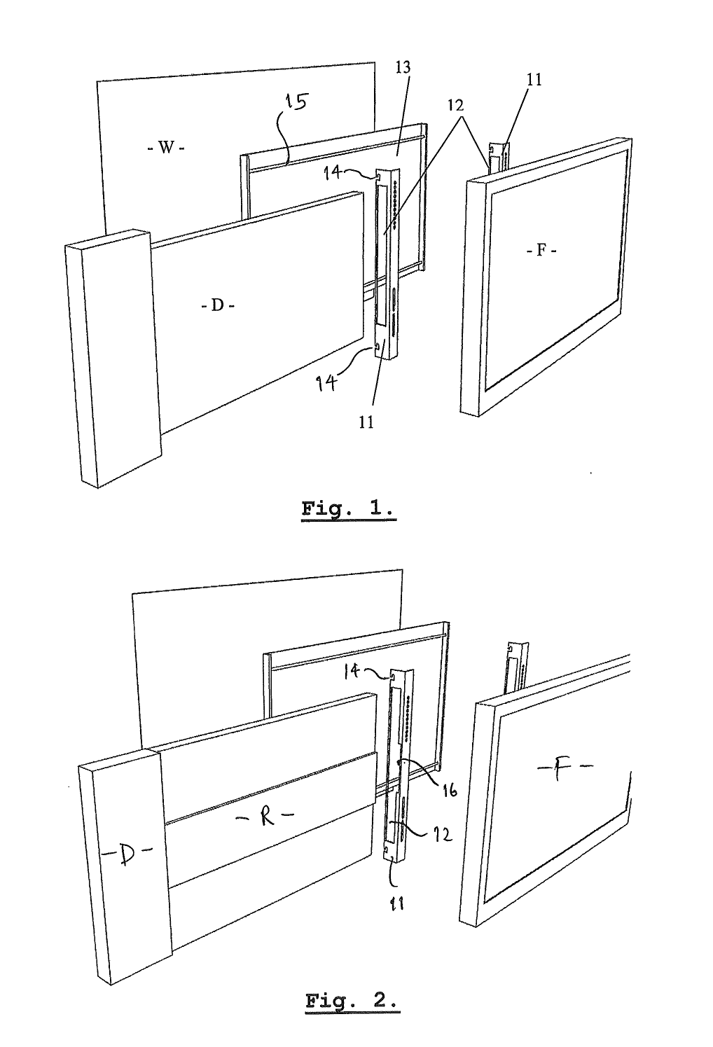

FIG. 1 illustrates a mounting apparatus according to the invention that comprises two mounting brackets 11 configured to receive, through openings or apertures 12, a peripheral device D or other similar enclosure or media related product.

In use of the apparatus as illustrated, mounting brackets 11 are firstly fastened to the rear of a flat panel display F, utilising a VESA pattern of fastener spacings, and secondly arranged on a wall mounted frame 13 that is screwed or otherwise affixed to a wall W. In the illustrated form, brackets 11 include hook-like channels 14 that receive rods 15 which span across the frame 13. However, it will be appreciated that a variety of means could be utilised to connect the brackets to the wall frame in a permanent or detachable way. Indeed, the frame (13) could alternatively be mounted on the rear of the display F, with brackets 11 permanently fastened to a wall. In this configuration the display would be removable, leaving the peripheral device D hanging on the wall.

In either case, brackets 11 are preferably easily demountable from and mountable back to the frame without a great deal of precision. Particularly, an edge of bracket 11 can slide along rod 15 until the channel/hook 14 is engaged to enable a display F to easily be hung onto a wall W.

Device D can initially slide into apertures 12 of the brackets whether display F is effectively mounted on the wall W or not. The invention assures that future access to device D is possible without removing display F from its wall mounted position, however, for overall ease of installation it is usually preferable to attach cabling between the display and device prior to wall mounting. In this case, preferably, cables need to be adjusted to the correct length between the invention and TV when installed for the first time. If the computer unit needs to be taken out during installation, cables are unplugged and then left hanging. When the computer unit returns to its original position and cables are reconnected, since their length remains adjusted, they are tensioned again to stay hidden behind the TV's edges.

As illustrated in FIGS. 1 and 2, apertures 12 are relatively elongate in order to accommodate a substantive part of a device D. According to the embodiment illustrated by FIG. 1 device D has two main parts, including a wider enclosure which would not fit into aperture 12 but, preferably, is still hidden behind display F when mounted on a wall or, more preferably, is extendable to an edge of the display F so that any important controls are accessible.

The design, function and layout of components within a device D is not a particular focus of the present invention, however, an example of a slim-profile personal computer is illustrated by FIG. 8 for completeness.

It will be apparent that aperture 12 generally needs to be sized in consideration of the device D which it will receive. Therefore, supply of the device and brackets may be proprietary (e.g. sold as a set) or, alternatively, designed according to an agreed standard size system.

FIG. 2 illustrates an embodiment that is functionally equivalent to that of FIG. 1; however, it will be apparent that device D includes an additional ridge R which is duly accommodated by a channel 16 formed in the main receiving aperture 12. Any appropriate shape of the device D could be accommodated by a corresponding aperture 12 as is necessary or practical.

Mounting bracket 11 may be considerably wider than illustrated, with a corresponding aperture 12 to receive a complete “desktop” computer housing. However, in the illustrated and preferred form, the part of the enclosure that slides into the mounting struts 11 is intended to be thin enough not to interference with any bolts being used to mount the struts to the back of the flat panel in a standard VESA pattern or the mounting system used to attach it to the wall.

The apparatus can then hook to a wall, ceiling or stand plate. It should be noted that the illustrated hooking mechanism allows lower overall thickness of the apparatus and therefore closer proximity to the wall, and this means there is more available space for the enclosure itself.

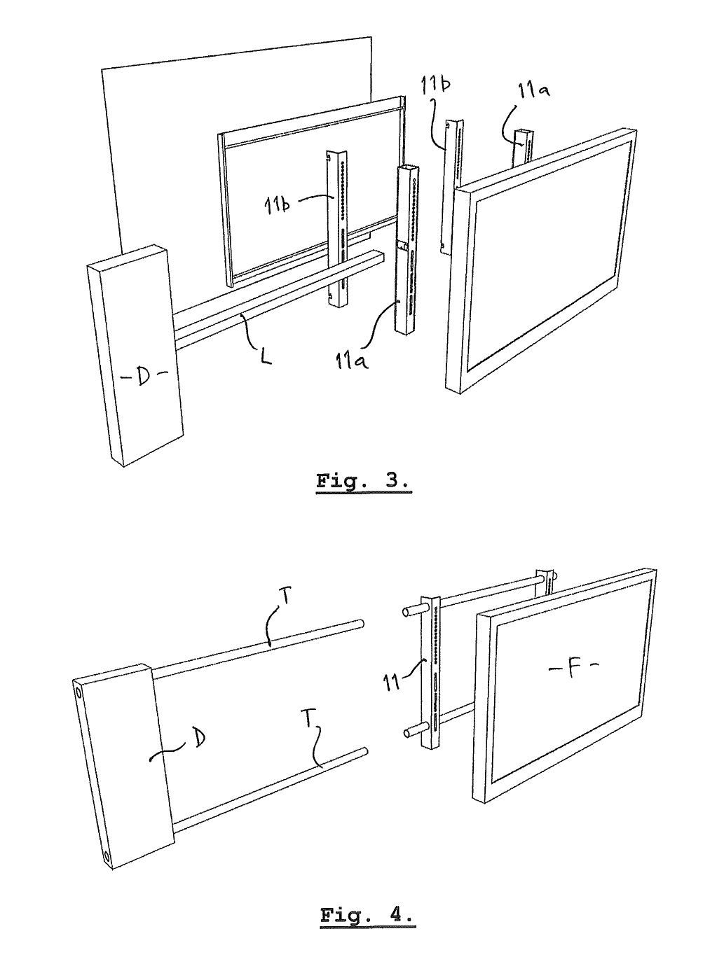

FIG. 3 illustrates an embodiment where device D has a more rod-like projection L which is to be received by an aperture 12 that is relatively much smaller than that shown by FIG. 1 or 2. In this case the projection L of the enclosure/device D allows it to slide in and out of the bracket but it is not large enough to enclose working parts therewithin as would be the case in FIGS. 1 and 2.

It is possible that, as illustrated in FIG. 3, a device D (which may comprise a peripheral device associated with the display monitor F) slides into place via projections L through mounting struts 11a that can, in turn, be attached directly to the brackets/struts 11b of another complete mounting mechanism e.g. wall mount or plate, ceiling arm, floor stand etc. The second pair of mounting struts 11b in FIG. 3 (behind the struts 11a that the enclosure slides into) represent any compatible third party mounting mechanism.

In this sense it should be clear that the invention is effectively an apparatus (bracket) which includes the means for receiving the separate device, enclosure or component and may not itself necessarily be connected directly to the wall (or display). In other words, there can be intermediate components. However, the apparatus is capable of supporting the weight of a flat panel display via its fastenings.

In a further embodiment it will be apparent that the mounting brackets of the invention could be “stacked” with any number of peripheral devices mounted behind the display screen in separate openings.

FIG. 4 shows two sliding telescopic rods/tubes T in place of box section projections L. This arrangement particularly allows enough space within the mounting strut 11 for the sliding parts not to interfere with bolt heads that may attach the display F to the strut and the strut to the wall. The bolts can pass all the way though or just be attached from panel to strut and strut to wall/stand/mount using any standard VESA configurations.

As mentioned previously, the apparatus can be attached to a wall indirectly using a wall plate (frame 13) or another mounting system. This allows the unit to be removed from the wall/stand etc together with (still attached to) the flat panel, which makes it easier to remove the mount, enclosure and flat panel together as one. Also as mentioned, the panel F is attached to the mounting struts using standard VESA configuration bolts before the struts are attached to the wall plate with the four hooks (14) at the four corners of each strut, allowing the full device to be easily lifted into place and hung on the wall. Cabling between electronic devices may already in place, so the only further requirement is plugging the device(s) into an electrical socket.

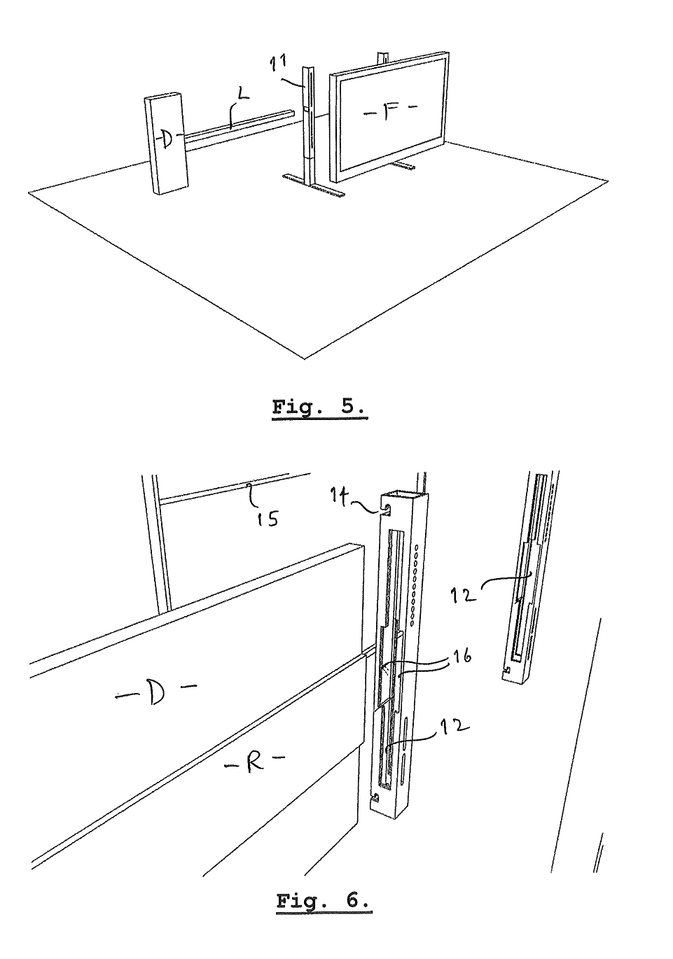

FIG. 5 shows generally the same apparatus as FIG. 3 mounted to a floor stand strut 11 rather than a wall. The struts are not affected structurally by the sliding enclosure holes 12 thus ensuring stability of the apparatus once placed on a flat surface such as floor or table; or hung from a ceiling. Once the enclosure is installed and slides to the desired position allowing relevant access, it is preferably secured in place so that the enclosure, apparatus and floor mount become one, making it easy to move about in the case of a wheeled stand for example, whilst being stable and secure.

Referring to FIG. 6 (similar in shape and some aspects to FIG. 2) the large openings 12 for sliding of the device in the mounting struts 11 are shaped with channels 16 on both sides to allow bolt heads not to interfere with the sliding enclosure on either side. The bolts can therefore be placed from the flat panel to the strut and then from the strut to the wall or stand. This allows universal VESA compatibility on both the flat panel display and the wall plate/stand/wall mount as well as allowing the enclosure to slide in and out of the mounting struts outside of the minimum VESA compatible size. As above this means that the enclosure device D can be permanently positioned at the edge of a variety of different sizes of flat panel displays as well as to allow for easy access for connectivity as well as access for upgrades and maintenance etc.

It should be noted with reference to FIG. 6 that strut/bracket 11 itself is a box section length, in contrast to the L section of FIGS. 1 and 2, for additional stability.

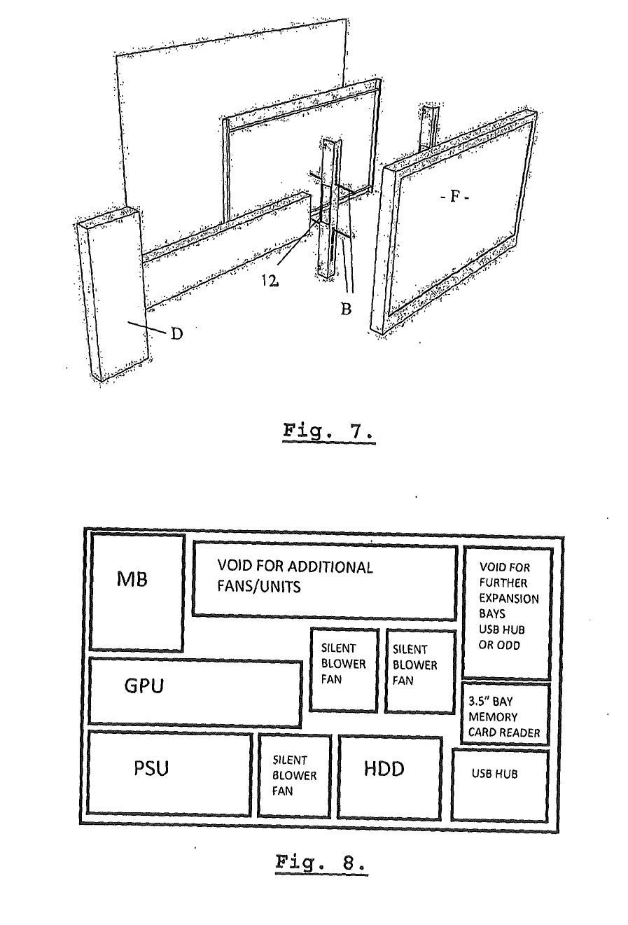

FIG. 7 illustrates a further variant of opening size 12 where the narrower part of the enclosure D that slides into the brackets 11 is a specific height so that it fits within the standard VESA mounting screw distance, i.e. VESA bolts B can be driven all the way through from the TV display to the wall, through the brackets, and it will not interfere with the sliding mechanism. The height of the enclosure (just less that the distance between the VESA bolts) is sufficient to house working parts for the PC/device.

In further embodiments the mounting struts can be wider to allow for staggered placement of the Flat Panel VESA mounting mechanism to the mounting struts and a third-party universal VESA mounting brackets or wall plates. The mounting struts closest to the wall can be attached through either bolt holes opposite those of the ones used to attached the primary struts to the flat panel or through the other set of bolt holes to the right of those opposite. This allows the enclosure to slide inside the extra bracket width and to be less obtrusive when retracted behind the TV.

In practice access to the mounting bolts can be made possible by making the brackets as two U-shaped symmetrical mating profiles. These are then held together by two transversal bolts at the top and bottom ends.

In general, in all embodiments once the enclosure is inside the mounting apparatus it can be secured in place using security bolts (not illustrated); firstly to ensure there is no movement of the enclosure within the apparatus and, secondly, that the unit effectively becomes one with the flat panel display and mounting apparatus (and can be removed and relocated as one if desired) and also to prevent theft or damage of the enclosure itself should the flat panel be positioned in public areas for example. By virtue of the sliding mechanism, the device can be located at a convenient position and this provides more flexibility than prior art mounting brackets that fix a unit in place at one specified position.

While the preferred embodiment as illustrated generally requires two (identical) mounting brackets, any number of brackets could be used as practical. Indeed, a single laterally wider bracket with an opening all the way through its width will achieve the purpose of the invention, but uses more material than is necessary in practice.

### INDUSTRIAL APPLICABILITY

The brackets and device/enclosure according to the invention can be manufactured from any suitable material, e.g. metal or plastics, designed to meet strength requirements primarily dictated by the size of the flat panel display.

It can be further noted that the bracket according to the invention could be utilised in the hanging of other objects (i.e. not only electronic equipment). One example may be artwork or photographic frames. Likewise, the bracket itself is suitable for mounting other non-electronic equipment.

1-14. (canceled)

15. A mounting apparatus including a bracket for mounting behind a flat panel display and adapted to receive a separate device, such that said device can be slidable into and out from behind the flat panel display when it is mounted thereto, to be locatable at a range of slidable positions.

16. The mounting apparatus of claim 15 wherein, in use, the device is slidable to a position adjacent an outside edge of the flat panel display.

17. The mounting apparatus of claim 15 wherein the bracket includes an opening for enabling the separate device to be slidably received.

18. The mounting apparatus of claim 15 including a fixing element such that the device can be secured in a user-customisable place, prohibiting further sliding movement.

19. The mounting apparatus of claim 15 further including a wall mount element for demountably receiving the bracket thereto.

20. The mounting apparatus of claim 15 wherein the bracket includes a VESA pattern of holes to align with the rear of the flat panel display.

21. The mounting apparatus of claim 15 including a tubular portion in the bracket for telescopically receiving a tubular portion of the device.

22. The mounting apparatus of claim 15 including a shaped opening for slidably receiving a like-shaped part of the device.

23. The mounting apparatus of claim 15 comprised of two or more brackets aligned to receive the separate device.

24. A combination of the mounting apparatus of claim 17 with a peripheral device, wherein the peripheral device includes a part sized to fit within the opening.

25. A bracket adapted to be coupled, at one side, to the rear of a first object to be mounted on a wall surface, the bracket providing an opening adapted to slidably receive a second object to be mounted between the first object and the wall, wherein the slidable engagement enables the second object to be configured at any desirable location relative to the first object.

26. A set of two or more brackets according to claim 25 arranged such that the respective openings are aligned to slidably receive the second object.

27. A device including a portion suitable for being received by the mounting apparatus of claim 15.

28. The device of claim 27 including a chassis which is expandable such that its outside edges are locatable a short distance from the edges of the flat panel display behind which it is mounted.

29. A combination of the mounting apparatus of claim 22 with a peripheral device, wherein the peripheral device includes a part sized to fit within the opening.

30. A combination of a mounting device and an electronic device, wherein in use the electronic device is to be mounted behind a flat panel display by the mounting device, the respective mounting device and electronic device including mating portions such that the electronic device can be slidable into and out from behind the flat panel display when it is mounted thereto by the mounting device, to be locatable at a range of slidable positions.
